(19) United States
(12) Patent Application Publication
(10) Pub. No.: US 2010/0109103 A1
(43) Pub. Date: May 6, 2010

(54) MEMS PACKAGE

(75) Inventor: Hung-Chang Tsao, Hsinchu (TW)

Correspondence Address: MARTINE PENILLA & GENCARELLA, LLP, 710 LAKEWAY DRIVE, SUITE 200, SUNNYVALE, CA, 94085, US

(73) Assignee: Windtop Technology Corp., a Taiwan Corporation, Hsinchu City (TW)

(21) Appl. No.: 12/511,908

(22) Filed: Jul. 29, 2009

(30) Foreign Application Priority Data
Nov. 5, 2008 (TW) 97142652

(51) Int. Cl. H01L 29/84; H01L 23/552; H01L 23/495

(52) U.S. Cl. 257/418; 257/660; 257/690; 257/E29.324; 257/E23.114; 257/E23.031

(57) ABSTRACT

The invention provides a MEMS package including: a MEMS chip including a first surface, a second surface, a first cavity, and a sensing device, the sensing device defining a first end of the first cavity; a leadframe including a second cavity and being electrically connected to the first surface of the MEMS chip, the second cavity being adjacent to the sensing device of the MEMS chip; a conductive layer disposed on the second surface of the MEMS chip to define a second end of the first cavity and grounded via the leadframe that is electrically connected to the conductive layer so as to provide electromagnetic shielding to the MEMS chip; and an encapsulant covering the MEMS chip, the leadframe, and the conductive layer to define an shape of the MEMS package and allowing outer surfaces of the leadframe to emerge from the MEMS package.

### CLAIM OF PRIORITY

This application claims priority to Taiwanese Application 97142652, which was filed on Nov. 5, 2008, and which is incorporated herein by reference.

### BACKGROUND OF THE INVENTION

1. Field of the Invention

The invention relates to a MEMS package, particularly to a cavity based MEMS sensor package.

2. Description of Related Art

A MEMS package or a cavity based MEMS sensor package contains a MEMS chip or a cavity based MEMS sensor chip in the packaging system similar to that of integrated chips or microelectronics. FIG. 1A is a schematic cross-sectional view of a conventional MEMS chip 100 having a sensing device 110 and a resonant chamber 120. The sensing device 110, for example, can include a vibration diaphragm 111, a fixed plate 112, and a piezoresistor 113. The basic operation of the MEMS chip 100 is that when an external signal transmits via the through-holes of the fixed plate 112 to reach the vibration diaphragm 111, the signal is amplified by the resonant chamber 120 to cause the vibration diaphragm 111 to produce mechanical vibration, and the piezoresistor 113 then converts the mechanical vibration into an electronic signal, thereby detecting the external signal. For the package of this type of MEMS chip, a resonant chamber is needed for the effective detection of an external signal, and therefore the package structure has to include a variety of chambers and channels to allow the sensing device of the MEMS chip to communicate with the external environment. Under the circumstances, the package is required to install additional components or carve out internal space in the original structure to form chambers and channels, for example, forming a front chamber and a back chamber each disposed at one side of the sensing device, the front chamber being the first chamber to receive the external signal and the back chamber facilitating or indirectly receiving the external signal. As shown in FIG. 1B, it is well known that an additional chamber 131 is provided in a conventional MEMS package. The chamber 131 is formed by covering a carved-out wafer material 140 on a MEMS chip 160, and a sealing member 150 is provided to seal the chamber 131. The chamber 132 in the MEMS chip and the additional chamber 131 form a front chamber and a back chamber respectively. However, since a MEMS device is often exposed to electromagnetic radiation in the operation environment, the converted signal may be subject to the electromagnetic interference. To guard against the radiation, as shown in FIG. 1C, a general method is to dispose a metallic cover 190 on the substrate 180, the metallic cover 190 being above and spaced apart from the MEMS chip 170. A space between the substrate 180 and the metallic cover 190 is formed as a resonant chamber (front chamber) 191, and a back chamber 192 is formed in the MEMS chip 170. By grounding the metallic cover 190, the aforementioned structure can exclude the interference caused by the electromagnetic radiation, as explained in U.S. Pat. No. 3,781,231. There are many techniques which provide improvements on the structure of a metallic cover, for example, the extra-ordinary protection within a metallic cover disclosed in Taiwan Patent No. 29961, and the integrally formed substrate/cover structure disclosed in U.S. Pat. No. 7,202,552. However, each of the structures uses a cover having a chamber, which not only increases package volume but also results in insufficient mechanical strength and compactness despite using more metal materials, and the packaging process is complicated and expensive.

In view of the above problems, the invention provides a MEMS package, specifically a cavity based MEMS sensor package that can overcome the aforementioned disadvantages.

### SUMMARY OF THE INVENTION

The invention relates to a MEMS package. According to an embodiment of the invention, a MEMS package includes: a MEMS chip having a first surface, a second surface, a first cavity, and a sensing device, the sensing device defining a first end of the first cavity; a leadframe having a second cavity and being electrically connected to the first surface of the MEMS chip, the second cavity being adjacent to the sensing device of the MEMS chip; a conductive layer disposed on the second surface of the MEMS chip to define a second end of the first cavity and grounded via the leadframe that is electrically connected to the conductive layer so as to provide electromagnetic shielding to the MEMS chip; and an encapsulant covering the MEMS chip, the leadframe, and the conductive layer so as to define the shape of the MEMS package and allowing outer surfaces of the leadframe to emerge from the MEMS package. In another embodiment, the MEMS package further includes an active component, such as a chip, or a passive component, such as a capacitor. In addition, the MEMS chip of the invention can further include a circuit component. Moreover, the MEMS package can further include an adhesive for bonding the conductive layer to the second surface of the MEMS chip. The MEMS package can also include a conductive adhesive for electrically connecting and bonding the leadframe to the first surface of the MEMS chip. Furthermore, the conductive layer can be electrically connected to the leadframe via a wire and a plurality of bonding pads, or alternatively, via a through-silicon via. In an embodiment of the invention, the aforementioned leadframe has an opening that communicates with the second cavity and that emerges from the MEMS package. Additionally, the volume of the first cavity can be changed by varying the shape of the conductive layer. Yet in another embodiment of the invention, an encapsulant covers the MEMS chip, the leadframe, and part of the conductive layer to define the shape of the MEMS package and allows outer surfaces of the leadframe and the uncovered part of the conductive layer to emerge from the MEMS package.

The MEMS package of the invention provides several advantages. When the MEMS package is acted on by electromagnetic radiation, the charges induced by the electromagnetic radiation in the conductive layer will be discharged to the external environment via a grounding device, and as a result the electromagnetic interference to the MEMS chip can be substantially reduced, thereby achieving the effect of electromagnetic shielding. The conductive layer is dual functional in that the conductive layer seals the first cavity of the MEMS chip by bonding itself to the MEMS chip and the conductive layer, in cooperation with a grounding device, provides electromagnetic shielding for the MEMS chip. Moreover, the volume of the first cavity can be increased by incorporating an additional space created by a protruded conductive layer, and thus the sensing device improves the damping characteristics to enhance the signal/noise ratio (SNR) by expanding the frequency response of the signals. For the MEMS package structure, the first cavity, the second cavity and the opening together form a passage for signal transmission by use of the MEMS chip, the leadframe and the conductive layer only so that the overall package remains a small volume or has a more compact structure. Furthermore, the encapsulant protects the MEMS chip, the leadframe and the conductive layer by providing shielding against external hazards such as moisture, light and particles. Besides, the encapsulant also makes the overall package easier to be grasped and improves the mechanical properties of the package.

### BRIEF DESCRIPTION OF THE DRAWINGS

The advantages and features of the invention will be appreciated by the various embodiments and examples set forth below in conjunction with the accompanied drawings. The drawings should be regarded as exemplary and schematic, and are shown not to scale and should not be implemented exactly as shown.

FIG. 1A shows a cross-sectional view of a conventional MEMS chip.

FIG. 1B shows a cross-sectional view of a conventional double-wafer MEMS structure.

FIG. 1C shows a cross-sectional view of a conventional MEMS package with a cover.

FIG. 2A shows a cross-sectional view of a MEMS package according to an embodiment of the invention.

FIG. 2B shows a cross-sectional view of a MEMS package in which the susceptor of the leadframe has no opening according to another embodiment of the invention.

FIG. 3A shows a perspective view showing the structural relationship of the MEMS chip, the leadframe and the conductive layer according to an embodiment of the invention.

FIG. 3B shows a perspective view of a MEMS package according to an embodiment of the invention.

FIG. 4 shows a partially enlarged cross-sectional view showing the adhesive overflow between the MEMS chip and the susceptor of the leadframe according to an embodiment of the invention.

FIG. 5 shows a partially enlarged cross-sectional view of a MEMS package having a through-silicon via grounding device according to an embodiment of the invention, wherein an encapsulant covers part of the conductive layer.

FIG. 6A shows a cross-sectional view of a MEMS package having a conductive layer different from that of FIG. 2A, according to an embodiment of the invention.

FIG. 6B shows a cross-sectional view of a MEMS package having a conductive layer different from that of FIG. 2A or FIG. 6A, according to an embodiment of the invention.

FIG. 6C shows a cross-sectional view of a MEMS package having a through-silicon via grounding device and a conductive layer with a cavity according to an embodiment of the invention.

FIG. 7A shows a cross-sectional view of a MEMS package having a passive component according to an embodiment of the invention.

FIG. 7B shows a cross-sectional view of a MEMS package having a chip according to an embodiment of the invention.

FIG. 7C shows a cross-sectional view of a MEMS package having a flip chip according to an embodiment of the invention.

### DETAILED DESCRIPTION OF THE INVENTION

The invention is explained using several embodiments and examples having numerous details. It should be noted that the details are exemplary and do not limit the invention.

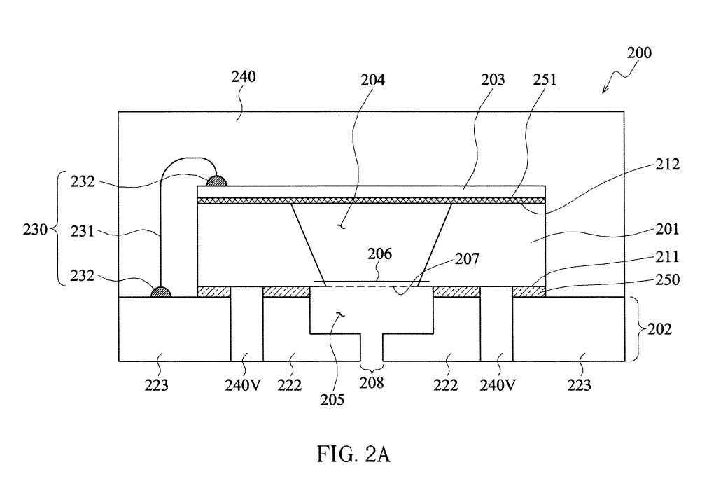

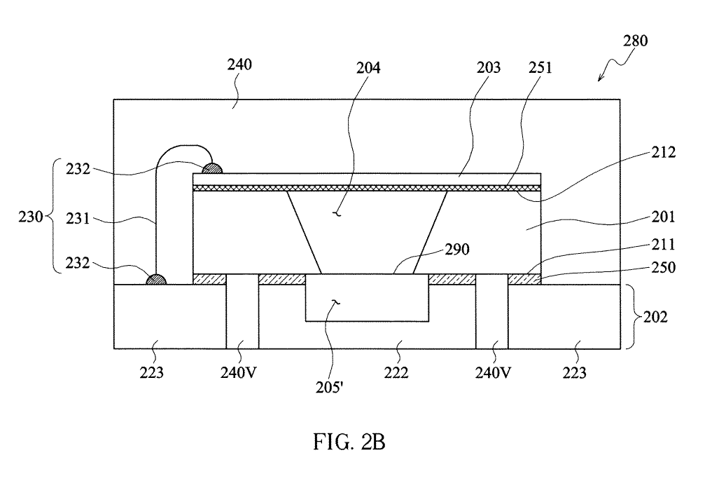

FIG. 2A shows a cross-sectional view of a MEMS package 200 according to an embodiment of the invention. The MEMS package 200 includes a MEMS chip 201, a leadframe 202, and a conductive layer 203. In the embodiment, the MEMS chip 201 is a silicon based chip having a Micro-Electro-Mechanical Systems (MEMS) device. As shown in FIG. 2A, the MEMS chip 201 has a first surface 211 and a second surface 212. The first surface 211 of the MEMS chip 201 is electrically connected to a leadframe 202. A conductive layer 203 is provided on the second surface 212 of the MEMS chip 201, which substantially covers the second surface 212. Alternatively, the conductive layer 203 covers only a part of the second surface 212. Additionally, the MEMS package 200 further includes a grounding device 230. The grounding device 230 includes a wire 231 and a plurality of bonding pads 232. The wire 231 electrically connects the conductive layer 203 to the leadframe 202 via the bonding pads 232. As can be seen from the embodiment, when the MEMS package 200 is acted on by electromagnetic radiation from external environment, charges will be induced in the conductive layer 203 due to the electromagnetic effect. The charges will reach the leadframe 202 via the grounding device 230, and eventually reach the ground plane at the outside of the MEMS package 200. As a result, the electromagnetic interference to the MEMS chip 201 is substantially reduced, thereby achieving the effect of electromagnetic shielding. Alternatively, the grounding device 230 may include a plurality of wires 231 and a plurality of bonding pads 232, wherein the plurality of wires 231 together lower the grounding resistance and further enhance the effect of electromagnetic shielding.

As also shown in FIG. 2A, the MEMS chip 201 includes a first cavity 204, wherein a diaphragm 206 and a fixed plate 207 are provided at the side of the first cavity 204 near the first surface 211. The fixed plate 207 has a plurality of through-holes, and the diaphragm 206 can freely vibrate. Alternatively, the fixed plate 207 can be provided on the other side of the diaphragm 206, namely, provided on top of the diaphragm 206 in FIG. 2A. Furthermore, the diaphragm 206 or the fixed plate 207 can be regarded as a part of the first surface 211 depending on the arrangement of the diaphragm 206 and the fixed plate 207. However, it is to be noted that the components defining the side of the first cavity 204 near the first surface 211 are not limited to the diaphragm 206 and the fixed plate 207 shown in FIG. 2A. Alternatively, two components sealing the first cavity 204 are provided at the side of the first cavity 204 near the first surface 211. Alternatively, a sensing device including at least a mechanical or electrical component is provided at the side of the first cavity 204 near the first surface 211.

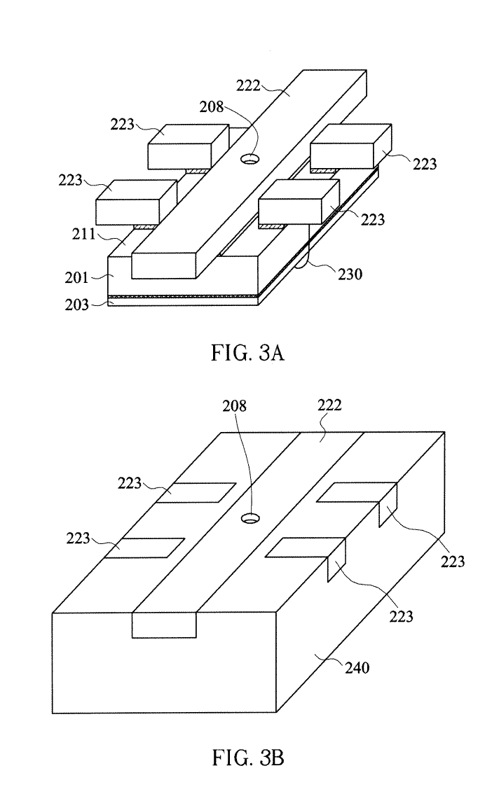

Moreover, as shown in FIG. 2A, the leadframe 202 includes a susceptor 222 and a plurality of conductive segments 223. FIG. 3A is a perspective view showing the structural relationship of the MEMS chip 201, the leadframe 202 (including a susceptor 222 and a plurality of conductive segments 223), and the conductive layer 203 of a MEMS package 200 with the first surface 211 facing upward according to an embodiment of the invention. FIG. 3A shows merely four of the plurality of conductive segments 223. Actually, the number of the conductive segments 223 is not limited to four. The plurality of conductive segments 223 are provided around the susceptor 222 that is configured to support the MEMS chip 201. One or more conductive segments 223 allow signals to be transmitted between the package 200 and an external device (such as a printed circuit board, not shown), and the remaining one or more conductive segments 223 are connected to the grounding device 230. Namely, the plurality of conductive segments 223 are configured as signal transmission ends or grounding ends respectively. Moreover, as shown in FIG. 2A, a second cavity 205 is formed on the susceptor 222. In FIG. 2A, the side of the second cavity 205 near the first cavity 204 is walled by the diaphragm 206 that functions between the two cavities. Specifically, the second cavity 205 communicates with the diaphragm 206 via the through-holes on the fixed plate 207 so that the diaphragm 206 can vibrate between the first cavity 204 and the second cavity 205. Preferably, the dimensions of the second cavity 205 are defined by the leadframe 202, the diaphragm 206 and optionally, part of the first surface 211. Preferably, a sensing device is provided between the first cavity 204 and the second cavity 205, the sensing device defines the side of the second cavity 205 that is near the first cavity 204.

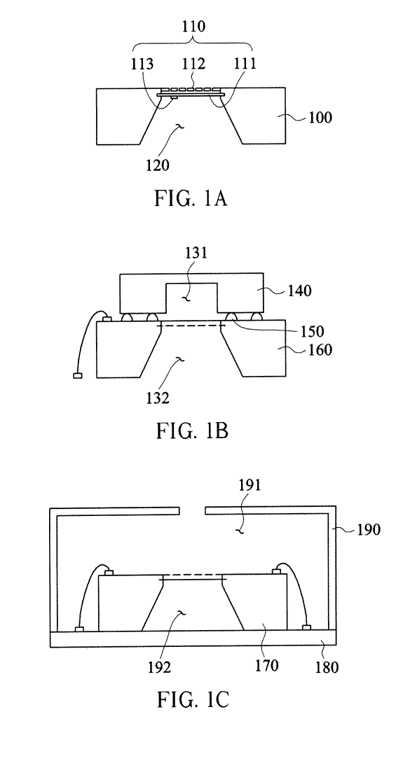

Furthermore, the susceptor 222 of the leadframe 202 has an opening 208, through which the second cavity 205 can communicate with external environment, allowing the transmission of signals through the opening 208. Based on the structure, signals such as sonic waves or pressure variations from external environment can be transmitted into the second cavity 205 through the opening 208. Resonance occurring in the first cavity 204 and the second cavity 205 cause the diaphragm 206 to vibrate, thereby the signals can be received by the MEMS chip 201. Conversely, MEMS chip 201 may produce signals which cause the diaphragm 206 to vibrate. Resonance thus occurs in the first cavity 204 and the second cavity 205, which makes the signals transmitted to the external environment via the opening 208. The MEMS package 200 having an opening 208 in accordance with the invention is applicable to microphones, pressure meters, barometers, tire gauges, altimeters, and so on. Depending on different applications, the MEMS package is configured to have a different predetermined maximum or minimum operating frequency, hence the dimensions of the first cavity 204 and the second cavity 205, and the area and depth (the distance from external environment to the second cavity 205) of the opening 208 being different, which affects the dimensions and structures of the MEMS chip 201 and the leadframe 202 (susceptor 222). Hence, the MEMS package in accordance with the invention, as illustrated by FIG. 2A, has a first cavity 204 and a second cavity 205 that can be of different shapes and volumes. For example, the shape of the cavity is designed such that the package has an adequate structural strength. In addition, as can be seen from the equation for the resonant frequency of an Helmholtz resonator, the resonant frequency increases with a decreasing cavity volume, and the resonant frequency increases with an increasing area of the opening or a decreasing depth of the opening. The second cavity 205 and the opening 208 can be formed by etching or pressing the leadframe 202 and then drilling a hole through the leadframe 202. Compared with the double-wafer bonding technique, as illustrated by FIG. 1B, forming the second cavity 205 directly on the leadframe 202 can expedite the manufacturing process and reduce the material cost.

In the MEMS package 200 shown in FIG. 2A, the conductive layer 203 is provided on the back side (the second surface 212) of the MEMS chip 201, and the front side (the first surface 211) of the MEMS chip 201 for transmitting signals is provided as facing downward and electrically connected to the leadframe 202. Under this configuration, the first cavity 204, the second cavity 205 and the opening 208 together form a passage for signal transmission by use of the MEMS chip 201, the leadframe 202 and the conductive layer 203 only so that the overall package remains a small volume or has a more compact structure.

Furthermore, FIG. 2A and FIG. 3B show that the MEMS package 200 in accordance with the invention further includes an encapsulant 240 covering the MEMS chip 201, the leadframe 202, the conductive layer 203 and the grounding device 230. The encapsulant 240 defines the shape of the MEMS package 200 and allows the outer surfaces of the leadframe 202 to emerge from the MEMS package 200. As shown in FIG. 3B, the exposed surfaces of the leadframe 202 on the MEMS package 200 are part of the surfaces of the susceptor 222 and the plurality of conductive segments 223. Apart from the exposed surfaces of the leadframe 202, the opening 208, the second cavity 205 communicating with the opening 208, the diaphragm 206 and the fixed plate 207, the encapsulant 240 prohibits the remaining part of the MEMS package 200 from contacting the external environment. As shown in FIG. 2A and FIG. 3B, the MEMS chip 201, the conductive layer 203, the grounding device 230, and the part of leadframe 202 excluding the exposed surfaces are all protected by the encapsulant 240. It should be noted that the encapsulant 240 covers the portion 240V between the susceptor 222 and the plurality of conductive segments 223, but not the opening 208. The encapsulant 240 can be formed from ceramics, plastic or the like, wherein the plastic material such as epoxy can be molded and cured to form the encapsulant. It should be noted that the encapsulant 240 protects the MEMS chip 201, the leadframe 202 and the conductive layer 203 by providing shielding against external hazards such as moisture, light and particles. Besides, the encapsulant 240 also makes the overall package easier to be grasped and improves the mechanical properties of the package.

Preferably, the MEMS package 201 includes a circuit component (not shown) on the first surface 211, such as a MEMS SoC circuit component. The circuit component can be connected to any sensing device or electronic component (not shown) on the diaphragm 206 and be connected to the leadframe 202 as well. The circuit component is shielded from the electromagnetic radiation by the grounded conductive layer 203. In another example, the MEMS circuit component is provided on another chip that is electrically connected to the MEMS package 200, where only the MEMS devices within the package are protected from the electromagnetic radiation by the conductive layer 203.

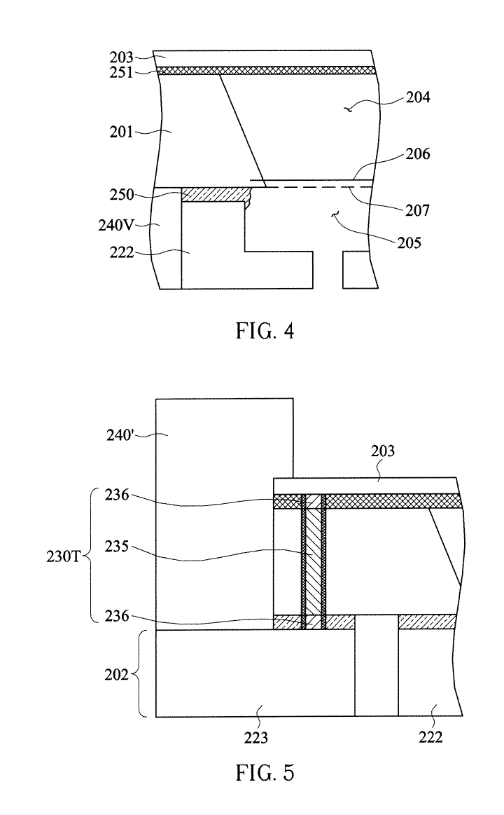

Preferably, the MEMS chip 201 can be electrically connected to the leadframe 202 (the susceptor 222 or the conductive segments 223) via a conductive adhesive 250 such as silver paste, conductive epoxy or the like. A shown in FIG. 4, since the second cavity 205 is designed to be wider than the diaphragm 206 and the fixed plate 207 of the MEMS chip 201, which has the merit that when overflowing adhesive of the conductive adhesive 250 exists between the MEMS chip 201 and the susceptor 222 and the overflowing adhesive flows down along the side wall of the second cavity 205 in the susceptor 222, the overflow will not affect the diaphragm 206 and the fixed plate 207. Therefore, the gluing and chip bonding processes can be more tolerant in accuracy control, thus the yield of package will be enhanced. The MEMS chip 201 can be connected to the conductive layer 203 via an adhesive 251. As shown in FIG. 2A and FIG. 4, the part of the adhesive 251 that does not contact the MEMS chip 201 will cure after being coated on the conductive layer 203, thus it will not affect the first cavity 204, the diaphragm 206 and the fixed plate 207. Alternatively, the adhesive 251 is only coated on the part of the conductive layer 203 that contacts the MEMS chip 201 via the adhesive 251.

Preferably, the grounding device includes a through-silicon via (TSV). According to an embodiment of the invention, FIG. 5 shows a partially enlarged cross-sectional view of a MEMS package 200 having a grounding device 230T that is electrically connected to the conductive layer 203 and the leadframe 202. The grounding device 230T includes a through-silicon via 235 and a plurality of conductive elements 236. Similar to the grounding device 230 described above, the charges induced by the electromagnetic radiation in the conductive layer 203 will reach the leadframe 202 via the grounding device 230T, and eventually reach the ground plane at the outside of the MEMS package 200, thereby providing electromagnetic shielding. The grounding device 230T consists of a plurality of through-silicon via 235 and a plurality of conductive elements 236 to reduce the grounding resistance and improve the effect of the electromagnetic shielding of the conductive layer 203. As shown in FIG. 5, the encapsulant 240′ covers part of the conductive layer 203. Alternatively, the encapsulant 240′ may cover no part of the conductive layer 203. In other words, some part or all of the conductive layer 203 is in contact with the external environment so as to achieve certain physical characteristics of the package, such as heat dissipation through the conductive layer 203.

As can be seen from the various embodiments and examples explained above, the MEMS package 200 of the invention not only has an improved overall mechanical strength and a smaller overall volume, but also offers a better protection for the internal components within the package, as compared with a conventional MEMS package (such as the one in FIG. 1C). Therefore, the MEMS package of the invention can be adapted for use in a more hostile environment, or in a smaller mobile device. Moreover, the conductive layer 203 is dual functional in that it seals the first cavity 204 of the MEMS chip 201 by bonding itself to the MEMS chip 201 and it, in cooperation with a grounding device 230 or 230T, provides electromagnetic shielding to the MEMS chip 201. In an application of the invention, the leadframe 202 of the MEMS package 200 is attached to a printed circuit board having a metal layer to create a double shielding for the MEMS chip. Namely, the conductive layer 203 and the printed circuit board having a metal layer shield the electromagnetic radiation from upper and lower sides of the package 200, thereby enhancing the electromagnetic shielding for the package. Moreover, one skilled in the art will understand that the conductive layer 203 is configured to have a thickness that is determined by the necessary strength required by the conductive layer 203 to withstand the pressure occurred during the molding of the encapsulant 240. Furthermore, for example, the conductive layer 203 can be a copper layer. The copper layer 203 can be attached to the MEMS chip 201 by first bonding a MEMS wafer to a copper plate and then after conducting circuit probe on the bonded wafer sawing the bonded wafer to form individual MEMS chips 201, each with a conductive layer 203. This simple manufacturing process of adhering the conductive layer 203 to the MEMS chip 201 by using the wafer-level bonding technique does not require very high accuracy for the process and therefore brings the cost down.

According to an embodiment of the invention, as shown in FIG. 2B, a MEMS package 280 has most of the technical features of the MEMS package 200 in FIG. 2A, except that, first, the diaphragm 206 and the fixed plate 207 in FIG. 2A are now replaced by a more general sensing device 290 in FIG. 2B, and second, the susceptor 222 in FIG. 2B has no opening so that the second cavity 205′ forms a closed chamber. Apart from the two differences, the MEMS package 280 has all the technical characteristics of the MEMS package 200, and can be configured to all the variations of the MEMS package 200 described above. Here, the sensing device 290 is provided on the MEMS chip 201, and it defines one end of the first cavity 204 near the first surface 211. The second cavity 205′ does not communicate with the external environment and totally protects the sensing device 290. The second cavity 205′ can be a vacuum or filled with gas or a filler. As compared with the double-wafer bonding structure (as shown in FIG. 1B), the second cavity 205′ can be formed by etching or stamping the leadframe 202. It should be noted that the invention allows the conductive adhesive 250 bonding the MEMS chip 201 and the leadframe 202 to have a relatively low hermeticity, for as long as the encapsulant 240 completely encapsulate the package elements except those exposed surfaces of the leadframe, the portion 240V of the cured encapsulant 240 substantially seals the second cavity 205′ or enhance the overall hermeticity of the cavity. The MEMS package 280 without an opening in accordance with the invention is applicable to accelerometers, gyroscopes and so on.

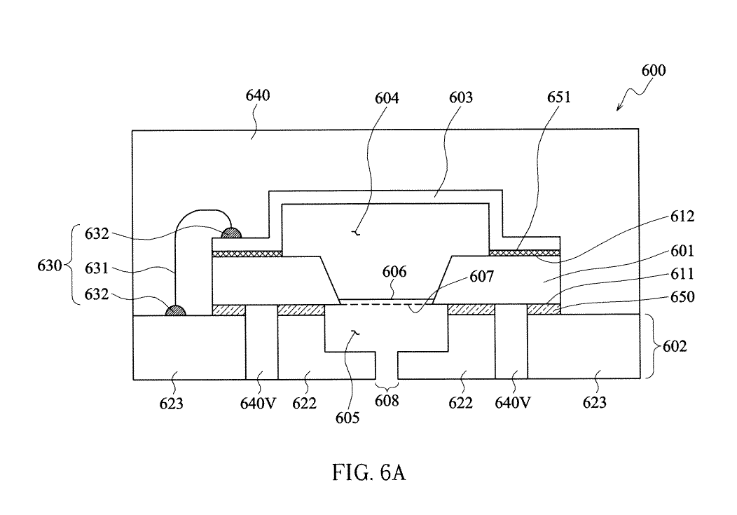

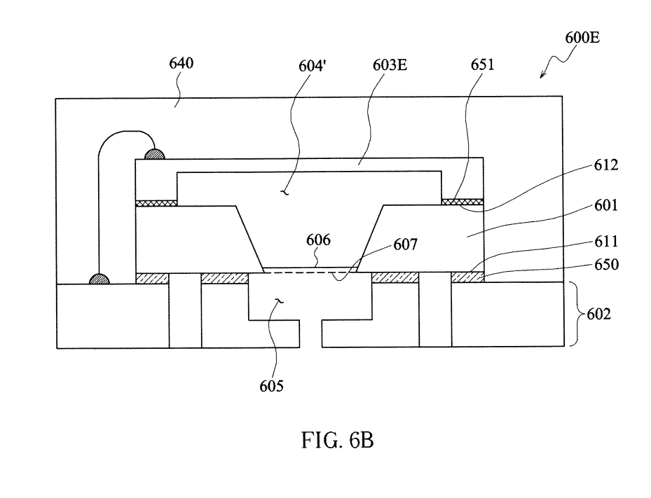

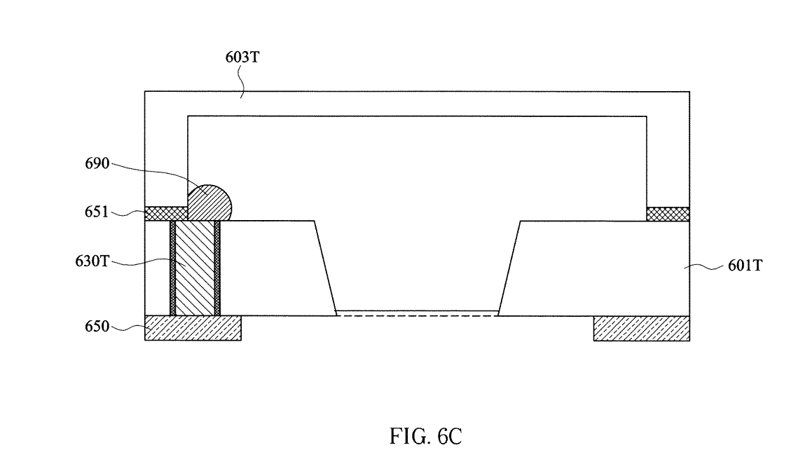

In other embodiments, the conductive layer 203 in the MEMS package 200 or 280 has many variations. According to an embodiment of the invention, a MEMS package 600 in FIG. 6A includes all the elements that are shown in FIG. 2A, where like reference numerals in the figures denote like elements, for example, MEMS chip 601 corresponds to MEMS chip 201, leadframe 602 corresponds to leadframe 202, and so on. However, the main difference is that the conductive layer 603 has a structure (shape) different from that of the conductive layer 203. The conductive layer 603, bonded to the second surface 612 of the MEMS chip 601 via the adhesive 651, forms an additional cavity between the conductive layer 603, the second surface 612, and the extension of the second surface 612 (an imaginary surface that extends from the second surface 612 over the cavity of the chip 601) such that the additional cavity of the conductive layer 603 and the cavity of the MEMS chip 601 together form a first cavity 604. That is, the conductive layer 603 has a structure protruded away from the second surface 612 of the MEMS chip 601. In other words, the first cavity 604 can increase or vary in volume by taking in the additional cavity created by the protruded conductive layer 603, and thus the vibration diaphragm 606 (or the sensing device in other embodiments of the invention) improves the damping characteristics to enhance the signal/noise ratio by expanding the frequency response of the signals. FIG. 6B shows another MEMS package 600E of the invention. The package 600E is the same as the package 600 except that the conductive layer 603E of the package 600E is structurally different from the conductive layer 603 of the package 600. Still, similar to the conductive layer 603, the conductive layer 603E forms an additional cavity that forms a first cavity 604′ together with the cavity of the chip 601. The additional cavity formed by the conductive layer 603 or 603E can be formed by etching or stamping the conductive layer. In related art, a long period of time must be spent to deep etch a cavity with a sufficient volume in the MEMS chip, making the etching process time-consuming and costly. The invention enables relatively fast mechanical polishing of the MEMS wafer followed by fast shallow etching on the wafer, which is then bonded to a pre-etched or pre-stamped metal plate and sawed to obtain individual chips, each of which is attached with a conductive layer having the additional cavity. In an example, the MEMS package of the invention can use a thinner MEMS wafer, which, after being shallow etched during the manufacturing process, can have a volume of the first cavity 604 or 604′ “restored” or increased by bonding to the conductive layer 603 or 603E having the additional cavity. Namely, the smaller cavity volume of the thinner MEMS chip is compensated by adding the additional cavity of the conductive layer. According to another embodiment of the invention, FIG. 6C shows that a MEMS chip 601T has a through-silicon via grounding device and a cavity based conductive layer (leadframe and encapsulant not shown). In FIG. 6C, the conductive layer 603T is attached to the MEMS chip 601T via the adhesive 651. The through-silicon via grounding device 630T is electrically connected to the conductive layer 603T via a conductive bump 690 that is in electrical contact with the conductive layer 603T and the through-silicon via grounding device 630T. The through-silicon via grounding device 630T is also electrically connected to the external environment via the conductive adhesive 650 (and via the leadframe). As a result, the conductive layer 603T is grounded to provide electromagnetic shielding, and it contributes to define part of the back chamber of the chip.

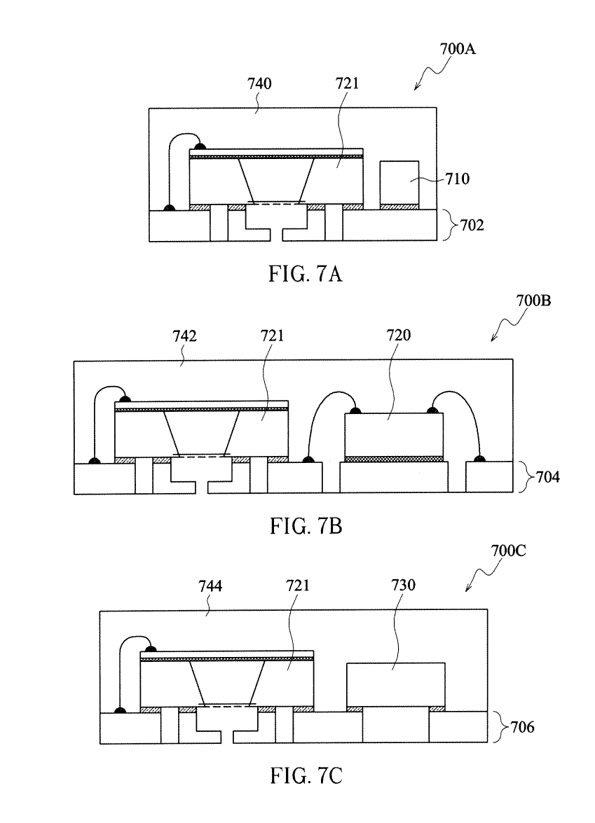

The MEMS package of the invention can further include other active or passive components. According to an embodiment of the invention, as shown in FIG. 7A, a MEMS package 700A can include all the technical features and their variations of the MEMS package 200, 280, 600, or 600E and further includes a passive component 710. The passive component 710 is provided on the leadframe 702 and covered by the encapsulant 740. The passive component 710 is electrically connected to the MEMS chip 721, which includes all the technical features and their variations of the MEMS chip in the MEMS package 200, 280, 600, or 600E. For example, the passive component 710 is a capacitor provided at the signal output end of the MEMS chip to enhance the electromagnetic shielding against a certain range of frequencies, such as the radio frequencies used in the GSM or 3G standard.

Alternatively, the MEMS package of the invention can be configured as a multi-chip module (MCM) package, in which the MEMS chip is coplanar or stacked with another chip provided within the package. For example, a MEMS package 700B shown in FIG. 7B can include all the technical features and their variations of the MEMS package 200, 280, 600, or 600E and further includes a chip 720 that is covered by the encapsulant 742. The chip 720 is electrically connected to the leadframe 704 via wires. Namely, the chip 720 may then be electrically connected to the MEMS chip 721. Moreover, as shown in FIG. 7C, a MEMS package 700C can include all the technical features and their variations of the MEMS package 200, 280, 600, or 600E and further includes a flip chip 730 that is covered by the encapsulant 744. The flip chip 730 is electrically connected to the leadframe 706. In either FIG. 7B or 7C, the MEMS chip 721 can include all the technical features and their variations of the MEMS chip in the MEMS package 200, 280, 600, or 600E.

While the invention has been shown and described with reference to several embodiment thereof, and in terms of the illustrative drawings, it should not be considered as limited thereby. Various possible modifications, alterations, and equivalents could be conceived of by one skilled in the art to the form and the content of any particular embodiment, without departing from the scope of the invention.

What is claimed is:

1. A MEMS package, comprising:
a MEMS chip including a first surface, a second surface, a first cavity, and a sensing device, the sensing device defining a first end of the first cavity;
a leadframe including a second cavity and being electrically connected to the first surface of the MEMS chip, the second cavity being adjacent to the sensing device of the MEMS chip;
a conductive layer disposed on the second surface of the MEMS chip to define a second end of the first cavity and grounded via the leadframe that is electrically connected to the conductive layer so as to provide electromagnetic shielding to the MEMS chip; and
an encapsulant covering the MEMS chip, the leadframe, and the conductive layer to define the shape of the MEMS package and allowing outer surfaces of the leadframe to emerge from the MEMS package.

2. The MEMS package of claim 1, wherein the MEMS chip further includes a circuit component provided on the first surface of the MEMS chip.

3. The MEMS package of claim 1, further comprising an adhesive for bonding the conductive layer to the second surface of the MEMS chip.

4. The MEMS package of claim 1, further comprising a conductive adhesive for electrically connecting the leadframe to the first surface of the MEMS chip.

5. The MEMS package of claim 1, wherein the conductive layer is electrically connected to the leadframe via a wire and a plurality of bonding pads.

6. The MEMS package of claim 1, wherein the conductive layer is electrically connected to the leadframe via a through-silicon via.

7. The MEMS package of claim 1, wherein the leadframe further includes an opening that communicates with the second cavity and emerges from the MEMS package.

8. The MEMS package of claim 1, wherein the volume of the first cavity is changed by varying the shape of the conductive layer.

9. A MEMS package, comprising:
a MEMS chip including a first surface, a second surface, a first cavity, and a sensing device, the sensing device defining a first end of the first cavity;
a leadframe including a second cavity and being electrically connected to the first surface of the MEMS chip, the second cavity being adjacent to the sensing device of the MEMS chip;
a conductive layer disposed on the second surface of the MEMS chip to define a second end of the first cavity and grounded via the leadframe that is electrically connected to the conductive layer so as to provide electromagnetic shielding to the MEMS chip;
an electronic component electrically connected to the leadframe; and
an encapsulant covering the MEMS chip, the leadframe, the conductive layer, and the electronic component to define the shape of the MEMS package and allowing outer surfaces of the leadframe to emerge from the MEMS package.

10. The MEMS package of claim 9, wherein the electronic component is a passive component.

11. The MEMS package of claim 9, wherein MEMS chip further includes a circuit component provided on the first surface of the MEMS chip.

12. The MEMS package of claim 9, further comprising an adhesive for bonding the conductive layer to the second surface of the MEMS chip.

13. The MEMS package of claim 9, further comprising a conductive adhesive for electrically connecting the leadframe to the first surface of the MEMS chip.

14. The MEMS package of claim 9, wherein the conductive layer is electrically connected to the leadframe via a wire and a plurality of bonding pads.

15. The MEMS package of claim 9, wherein the conductive layer is electrically connected to the leadframe via a through-silicon via.

16. The MEMS package of claim 9, wherein the leadframe further includes an opening that communicates with the second cavity and that emerges from the MEMS package.

17. The MEMS package of claim 9, wherein the volume of the first cavity is changed by varying the shape of the conductive layer.

18. A MEMS package, comprising:
a MEMS chip including a first surface, a second surface, a first cavity, and a sensing device, the sensing device defining a first end of the first cavity;
a leadframe including a second cavity and being electrically connected to the first surface of the MEMS chip, the second cavity being adjacent to the sensing device of the MEMS chip;
a conductive layer disposed on the second surface of the MEMS chip to define a second end of the first cavity and grounded via the leadframe that is electrically connected to the conductive layer so as to provide electromagnetic shielding to the MEMS chip; and
an encapsulant covering the MEMS chip, the leadframe, and part of the conductive layer to define the shape of the MEMS package and allowing outer surfaces of the leadframe and the uncovered part of the conductive layer to emerge from the MEMS package.
